(19) United States
(12) Patent Application Publication
(10) Pub. No.: US 2010/0273297 A1
(43) Pub. Date: Oct. 28, 2010

(54) CHIP PACKAGING METHOD

(75) Inventor: CHING-YAO FU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/686,514

(22) Filed: Jan. 13, 2010

(30) Foreign Application Priority Data
Apr. 24, 2009 (CN) 200910107150.1

(51) Int. Cl. H01L 21/60

(52) U.S. Cl. 438/121; 257/E21.509

(57) ABSTRACT

In a method for mounting a chip on a substrate, a plurality of grooves are defined in the substrate. A plurality of pads are formed in the grooves. A height of each of the plurality of pads is less than a depth of each corresponding groove. The chip configured with a plurality of soldering balls is positioned on the substrate with the plurality of soldering balls being received in the plurality of grooves and contacting the plurality of pads respectively. The chip is mounted onto the substrate by a melting process.

### BACKGROUND

1. Technical Field

Embodiments of the present disclosure relate to chip packaging methods, and especially to a method of mounting a chip on a ceramic substrate.

2. Description of Related Art

In general packaging, soldering pads are directly disposed on and protrude from substantially even surfaces of a ceramic substrate, and a chip with soldering balls is mounted on the ceramic substrate by melting the soldering pads and the soldering balls together. However, during the melting process, the chip is prone to offset from the substrate which adversely affects connection therebetween.

FIG. 2 illustrates a commonly used process of mounting a chip 20 on a substrate 10 with an substantially even surface 101. The process includes forming a plurality of soldering pads 12 on an substantially even surface 101 of the substrate 10 and soldering the chip 20 with a plurality of soldering balls 30 on the substrate 10, the soldering balls 30 corresponding to soldering pads 12. However, in the soldering process, no means is provided to prevent the soldering pads 12 from deviating from the corresponding soldering balls 30, resulting in potential disconnection of the soldering balls 30 from the corresponding soldering pads 12.

Therefore, a need exists in the industry to overcome the described limitations.

### BRIEF DESCRIPTION OF THE DRAWINGS

FIG. 1A is a schematic diagram of a substrate of one embodiment of a method for mounting a chip thereon according to the present disclosure.

FIG. 1B is a schematic diagram of defining a plurality of grooves in the substrate of FIG. 1A.

FIG. 1C is a schematic diagram of mounting a chip onto the substrate of FIG. 2, wherein a plurality of pads are formed in the plurality of grooves.

FIG. 2 is a schematic diagram of a commonly used method for mounting a chip on a substrate.

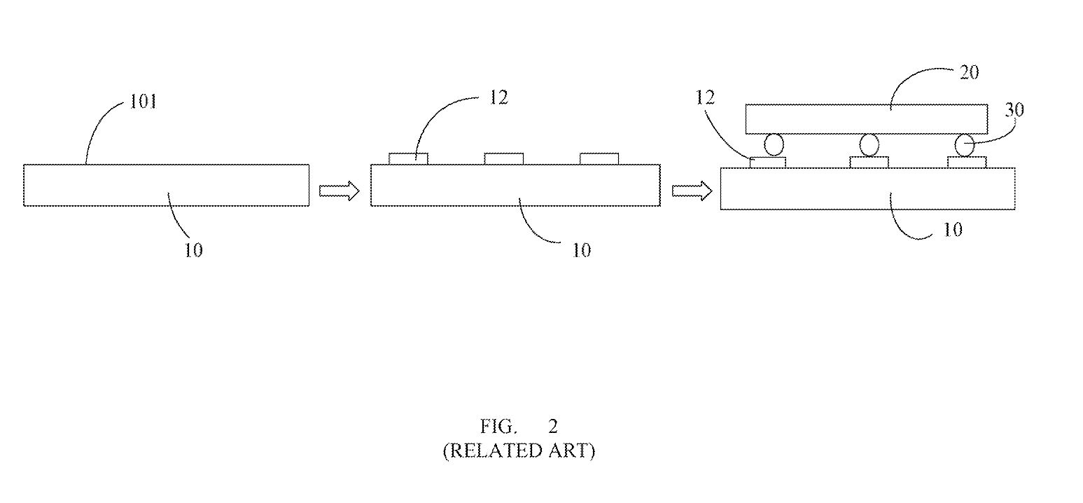

### DETAILED DESCRIPTION

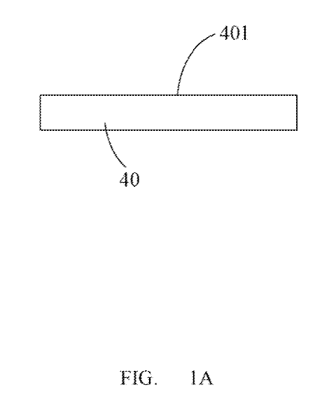

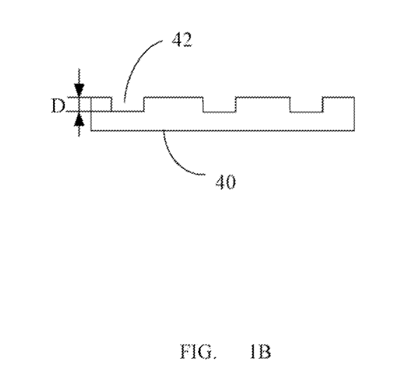

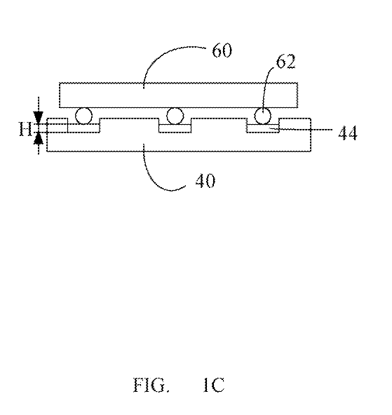

FIG. 1A-FIG. 1C are schematic diagrams of one embodiment of a method for mounting a chip 60 on a substrate 40 according to the present disclosure. The substrate 40 is a ceramic substrate with a substantially even surface 401 (see FIG. 1A). In the embodiment, a plurality of grooves 42 are defined in the surface 401 of the substrate 40 (see FIG. 1B) by precision tooling such as a laser or a punching method. The plurality of grooves 42 can be defined in various shapes, for example, square, circular, or elliptical.

A plurality of pads 44 are formed in the plurality of grooves 42 respectively by disposing and baking conductive adhesive on the bottom of the grooves 42. A height H of each of the pads 44 is less than a depth D of each corresponding groove 42 in the substrate 40 (see FIG. 1C).

The chip 60 is configured with a plurality of soldering balls 62. The chip 60 is positioned on the substrate 40 with the plurality of soldering balls 62 being received in the plurality of grooves 42 and contacting the plurality of pads 44 respectively. Then, the chip 60 is mounted onto the substrate 40 by a melting process. In the melting process, the soldering balls 62 are soldered together with the pads 44 in the grooves 42, without any substantial deviation because the difference of the height H of each of the pads 44 subtracting the depth D of each corresponding groove 42 avoids the soldering balls 62 from shifting from the pads 44. Thus, the chip 60 is mounted onto the substrate 40 correctly with good electrical connection performance (see FIG. 1C).

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A chip packaging method, comprising:
defining a plurality of grooves on a substantially even surface of a substrate;
placing a plurality of pads in the plurality grooves respectively, wherein a height of each of the plurality of pads is less than a depth of each corresponding groove;
positioning a chip configured with a plurality of soldering balls on the substrate, wherein the plurality of soldering balls are received in the plurality of grooves and contact the plurality of pads, respectively; and
mounting the chip onto the substrate by a melting process.

2. The chip packaging method as claimed in claim 1, wherein the plurality of grooves are defined in the substrate by a precision tooling method.

3. The chip packaging method as claimed in claim 2, wherein the plurality of grooves are defined in the substrate by a punching process.

4. The chip packaging method as claimed in claim 2, wherein the plurality of grooves are defined in the substrate by a laser process.
